(19) United States
(12) Patent Application Publication
(10) Pub. No.: US 2026/0087191 A1
(43) Pub. Date: Mar. 26, 2026

(54) REACHABILITY EVALUATION USING KINEMATIC MODEL AND TRAVERSAL COSTS

(71) Applicant: Intel Corporation, Santa Clara, CA (US)

(72) Inventors: Rodrigo Aldana Lopez, Zapopan (MX); Leobardo Campos Macias, Guadalajara (MX); Rafael De La Guardia Gonzalez, Leioa (MX); David Gomez Gutierrez, Tlaquepaque (MX); Julio Zamora Esquivel, West Sacramento, CA (US)

(21) Appl. No.: 19/403,475

(22) Filed: Nov. 28, 2025

(51) Int. Cl. G06F 30/13

(52) U.S. Cl. CPC G06F 30/13

(57) ABSTRACT

The present disclosure provides a system including processors and memory storing instructions that, when executed, cause the system to receive three-dimensional data representing an environment, including navigable surfaces, points of interest, and obstacles. The system constructs a reachability graph representing connections between navigable surfaces and points of interest. The system performs motion planning using a kinematic model by assigning traversal costs to paths that intersect with obstacles while maintaining connectivity through obstacles in the reachability graph. The system evaluates reachability to points of interest based on traversal costs and generates output identifying which points of interest are reachable.

### TECHNICAL FIELD

The present disclosure relates to automated industrial facility design systems, and more particularly to a system for evaluating human reachability and manipulability of components in industrial environments using kinematic models and cost-aware motion planning.

### BACKGROUND

Industrial facility design encompasses the planning and layout of complex operational environments such as manufacturing plants, semiconductor fabrication facilities, processing plants, and logistics centers. These environments contain numerous mechanical, electrical, and structural components that must be accessible to human operators for routine operation, maintenance, inspection, and safety procedures.

Traditional facility design processes rely heavily on manual methods, with experienced engineers and technicians creating detailed layouts through iterative design cycles. These manual approaches are time-intensive and prone to errors, particularly when coordinating the spatial relationships between equipment, routing systems, and human access requirements. Design conflicts often emerge late in the development process, leading to costly modifications and project delays.

The industry has increasingly adopted automated design tools to address these challenges, including computer-aided placement systems, automated routing algorithms, and optimization software. These systems can efficiently generate layouts that satisfy geometric constraints, minimize routing distances, and optimize spatial utilization. However, existing automated approaches typically focus on equipment placement and connection routing without explicitly considering human accessibility factors.

Human operators must physically interact with various components throughout industrial facilities, including valves, gauges, control panels, switches, and maintenance access points. These interactions often involve complex manipulations in constrained spaces, such as rotating valve handles, reading instrument displays, or accessing service panels. Current design validation methods lack systematic approaches for verifying that human operators can reach and manipulate these components within the proposed facility layouts.

The absence of human-centered validation in automated design workflows can result in facilities where components are geometrically accessible but practically unusable due to spatial constraints, obstructions, or ergonomic limitations. Such issues typically surface during construction or commissioning phases, when remediation becomes expensive and disruptive to project timelines.

### BRIEF DESCRIPTION OF THE FIGURES

Non-limiting and non-exhaustive examples are described with reference to the following figures.

FIG. 1 illustrates a flowchart of a human-aware reachability and manipulability system for industrial design automation, according to aspects of the present disclosure.

FIG. 2 depicts an isometric view of a valve manipulation trajectory associated with a valve, according to aspects of the present disclosure.

FIG. 3 illustrates a semantic industrial model to reachability graph conversion process, according to aspects of the present disclosure.

FIG. 4A depicts a cost-aware reachability planning example showing a human navigation path routing around an obstructing element, according to aspects of the present disclosure.

FIG. 4B depicts the cost-aware reachability planning example of FIG. 4A showing the human navigation path passing through the obstructing element, according to aspects of the present disclosure.

FIG. 5 illustrates an isometric view of a temporary walkway placement example on structural elements, according to aspects of the present disclosure.

FIG. 6 depicts a manipulability simulation and clearance volume extraction example showing human models and a volumetric envelope, according to aspects of the present disclosure.

FIG. 7 illustrates a block diagram of a computing device, according to aspects of the present disclosure.

### DETAILED DESCRIPTION

The following description sets forth exemplary aspects of the present disclosure. It should be recognized, however, that such a description is not intended as a limitation on the scope of the present disclosure. Rather, the description also encompasses combinations and modifications to those exemplary aspects described herein.

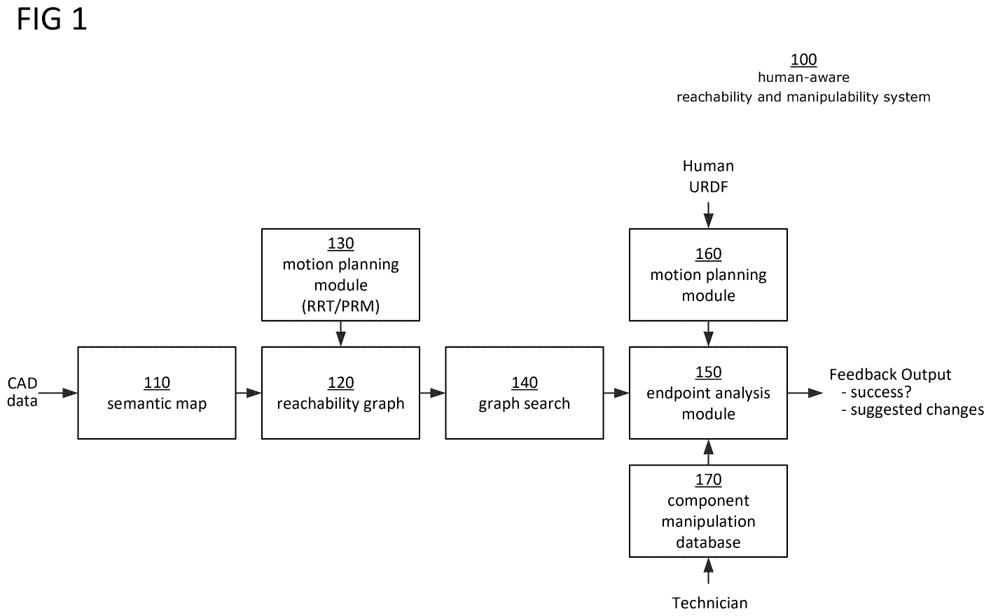

Referring to FIG. 1, a system 100 may be configured to perform human-aware reachability and manipulability analysis for industrial design automation. The system 100 may comprise one or more processors and a memory storing instructions that, when executed by the one or more processors, cause the system 100 to receive three-dimensional (3D) data representing an environment and process the 3D data through a series of interconnected modules to verify human accessibility and operability of components within the environment.

The system 100 may include a semantic map 110 that receives the 3D data as input. The semantic map 110 may extract and organize spatial information, object identities, walkable surfaces, and points of interest from the 3D data. In some cases, the semantic map 110 may be extracted from 3D design data in the Universal Scene Description (USD) format, thereby preserving high-level object identities and hierarchies. The 3D data may comprise one or more navigable surfaces, one or more points of interest, and one or more obstacles. The 3D data may comprise one or more semantic annotations identifying one or more object types, including walkable surfaces, stairs, ladders, valves, gauges, and entry points.

The semantic map 110 may include static structures, such as walls, ceilings, and slab edges, as distinct object categories. In some cases, the semantic map 110 may include dynamic elements that can change during the design process, such as tools, route geometries including pipes and cable trays, and movable equipment. The semantic map 110 may output processed spatial information to other components within the system 100.

As further shown in FIG. 1, the system 100 may include a reachability graph 120 that receives output from the semantic map 110. The reachability graph 120 may construct a network of human-navigable connections between entry points and points of interest within the environment. The reachability graph 120 may represent connections between one or more navigable surfaces and one or more points of interest. In some cases, the reachability graph 120 may model the space that a human operator can traverse on foot within the industrial environment.

The system 100 may include a motion planning module 130 that provides 3D rigid body motion planning to the reachability graph 120. The motion planning module 130 may generate feasible human-scale paths through constrained spaces when direct connections are not available in the reachability graph 120. In some cases, the motion planning module 130 may use sampling-based algorithms such as rapidly exploring random tree (RRT) or probabilistic roadmap (PRM) techniques.

With continued reference to FIG. 1, the system 100 may include a graph search 140 that receives input from the reachability graph 120. The graph search 140 may identify all reachable points of interest from designated entry points within the environment. The graph search 140 may evaluate reachability to the one or more points of interest based on traversal costs assigned to paths within the reachability graph 120. The graph search 140 may output results to subsequent processing modules for further analysis.

The system 100 may include an endpoint analysis module 150 that receives inputs from multiple sources within the system 100. The endpoint analysis module 150 may evaluate whether required manipulations are feasible given spatial constraints and may verify line-of-sight access for gauges or other visual components. In some cases, the endpoint analysis module 150 may serve as a final verification stage before generating actionable feedback for designers.

As shown in FIG. 1, the system 100 may include a motion planning module 160 that provides angular coordinates motion planning to the endpoint analysis module 150. The motion planning module 160 may operate based on human Unified Robot Description Format (URDF) data to simulate human kinematic constraints and motion capabilities. The motion planning module 160 may evaluate whether specific manipulation tasks can be performed within the environment's spatial constraints.

The system 100 may include a manipulation database 170 that supplies valve or other component manipulation trajectories and reference motions to the endpoint analysis module 150. The manipulation database 170 may store reference trajectories that are provided by technicians and may contain predefined motion patterns for various types of industrial components. In some cases, the manipulation database 170 may enable the system 100 to evaluate manipulability without requiring a custom trajectory definition for each component instance.

The system 100 may generate output identifying which of the one or more points of interest are reachable based on the processing performed by the interconnected modules. The output may indicate success or failure of reachability and manipulability checks, along with suggested changes to resolve any identified obstructions or access issues. In some cases, the system 100 may generate accessibility feedback identifying reachability and interaction feasibility for the one or more points of interest. The system 100 may provide this feedback to designers or automated routing tools to ensure human operability is maintained throughout the design process.

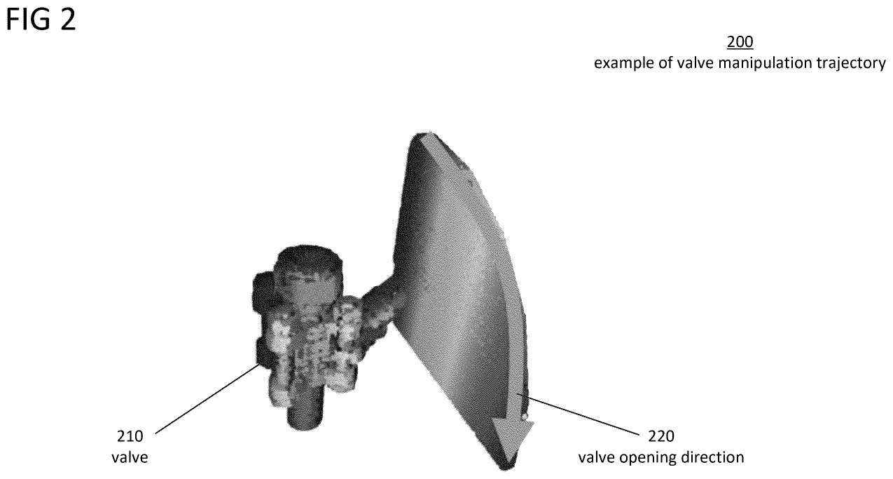

Referring to FIG. 2, a valve manipulation trajectory 200 may be associated with a valve 210 within an industrial environment. The valve manipulation trajectory 200 may be represented as a spatial path that extends from the valve 210, depicting the three-dimensional motion required for human interaction with the valve 210. The valve manipulation trajectory 200 may appear as a curved, multi-colored surface that transitions through a spectrum from the base near the valve 210 to the distal end, indicating the progression of the manipulation motion over time.

The valve opening direction 220 is indicated by an arrow along the trajectory, showing the intended direction of motion during valve operation. The valve opening direction 220 may provide spatial orientation information that guides the execution of the manipulation task within the industrial environment.

The manipulation database 170 may store reference manipulation trajectories as time-indexed trajectories of a human end effector relative to a component frame. In some cases, the manipulation database 170 may contain a collection of reference manipulation trajectories tied to known object models such as specific valve types. Each reference trajectory may be defined in a canonical frame and may include specific operations such as turning a handle clockwise for 90 degrees or pulling a lever along a defined path. The reference trajectories may be provided by technicians and stored as time-indexed sequences of human end effector positions, typically representing hand movements relative to the component frame.

When the system 100 encounters an instance of a component in an industrial layout, the system 100 may transform a reference trajectory to a pose of a component at a point of interest. The transformation process may use the component's rotation and translation parameters to convert the reference trajectory from the canonical frame into the world coordinate frame. This transformation approach may eliminate the need to define manipulation constraints individually for every object instance within the environment.

The system 100 may evaluate whether an interaction is performable by accessing a database of one or more reference trajectories associated with one or more interaction types. The endpoint analysis module 150 may retrieve appropriate reference trajectories from the manipulation database 170 based on the component type encountered at each point of interest. The system 100 may detect any collisions during execution of the transformed trajectory by using motion planning algorithms to validate all intermediate steps against surrounding geometry including pipes, supports, and cable trays. In some cases, the collision detection process may determine whether sufficient clearance exists for the human end effector to complete the manipulation task without interference from obstacles in the environment.

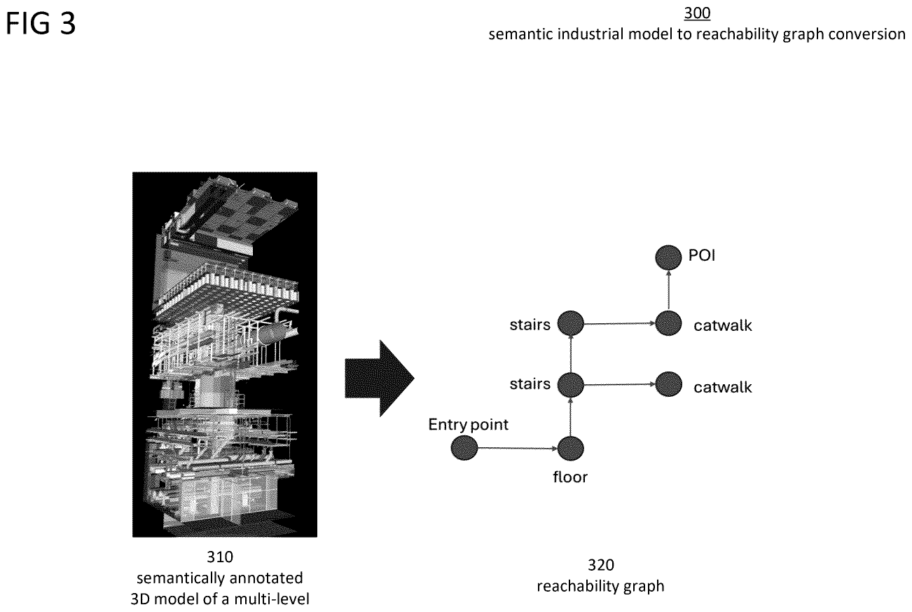

Referring to FIG. 3, a semantic industrial model to reachability graph conversion 300 may transform a semantically annotated 3D model 310 into a reachability graph 320. The semantically annotated 3D model 310 may depict a complex industrial structure with multiple levels, including tools, structural elements, platforms, and routing components rendered in various colors. The semantically annotated 3D model 310 may contain semantic information identifying different object types such as walkable surfaces, stairs, equipment, and points of interest within the industrial environment.

The reachability graph 320 may represent the human-navigable portions of the environment as a network of nodes and edges. As shown in FIG. 3, the reachability graph 320 may include several labeled nodes corresponding to different surface types and locations. A POI (Point of Interest) node may appear at the top of the reachability graph 320, connected by an edge to a catwalk node. Two instances of stairs nodes may be shown in the middle portion, each connected to the corresponding catwalk nodes via edges. An entry-point node may be positioned near the bottom of the reachability graph 320 and connected to a floor node. The floor node may also be connected to one of the stairs nodes, forming an interconnected network.

The semantic industrial model to reachability graph conversion 300 may extract walkable surfaces, entry points, and points of interest from the semantically annotated 3D model 310 to construct the nodes and edges of the reachability graph 320. The reachability graph 320 may serve as a computational representation that enables determining whether human operators can navigate from entry points to various points of interest throughout the industrial environment.

The system 100 may construct the reachability graph 120, 320 using voxelization or segmentation of walkable surfaces into node patches. In some cases, all walkable surfaces may be voxelized or segmented into node patches, where each node may record position, surface normal, and class information such as floor, catwalk, or stair tread. The node-generation process may produce discrete spatial representations of navigable areas within the industrial environment.

The system 100 may generate edges between adjacent surfaces within walking or stepping distance during the construction of the reachability graph 120. The edge generation process may include special logic to handle stairs and ladders at elevation transitions. In some cases, the special logic may handle jumpable or climbable surfaces for low ledges, bridges, or catwalks with adjacent structure. The edge generation may create connections that represent feasible human transitions between different navigable surfaces within the environment.

The system 100 may perform motion planning using a kinematic model by assigning traversal costs to one or more paths that intersect with one or more obstacles while maintaining connectivity through the one or more obstacles in the reachability graph 120. The motion planning process may evaluate spatial constraints and human movement capabilities when determining path feasibility. In some cases, the system 100 may maintain connectivity through obstacles by assigning appropriate traversal costs rather than completely blocking paths that encounter dynamic elements.

For each valve, gauge, or access zone, the system 100 may search for the nearest walkable node within a specified radius and elevation band during POI anchoring. If no direct graph connections can be made to a POI, the system 100 may launch a motion planning algorithm, such as RRT (Rapidly exploring random tree), to search for a feasible human-scale path from nearby graph nodes. The motion planning algorithm may sample a human-sized box through the environment, constrained to land only on valid surfaces. Successful paths may be integrated into the reachability graph 120 to ensure comprehensive coverage of accessible areas within the industrial environment.

he kinematic model used by the system 100 may represent various types of anthropomorphic or mobile agents depending on the operational requirements of the industrial environment. In some cases, the kinematic model may represent a human operator with articulated limbs and joint constraints based on human ergonomic data. In other cases, the kinematic model may represent a humanoid robot configured to perform manipulation tasks similar to human operators. The kinematic model may alternatively represent a wheeled robot configured to navigate the industrial environment on wheels or tracks, wherein the reachability analysis may focus on ground clearance, turning radius, and traversable surface types rather than bipedal locomotion constraints. In some cases, the kinematic model may represent a quadruped robot configured to navigate using four legs, enabling access to areas that may be challenging for wheeled platforms or human operators, such as uneven terrain, stairs, or elevated structures. The system 100 may support multiple kinematic models simultaneously, allowing designers to evaluate accessibility for different agent types within the same industrial facility layout. The selection of kinematic model may depend on factors including the types of tasks to be performed, environmental constraints, safety requirements, and operational preferences for the specific industrial application.

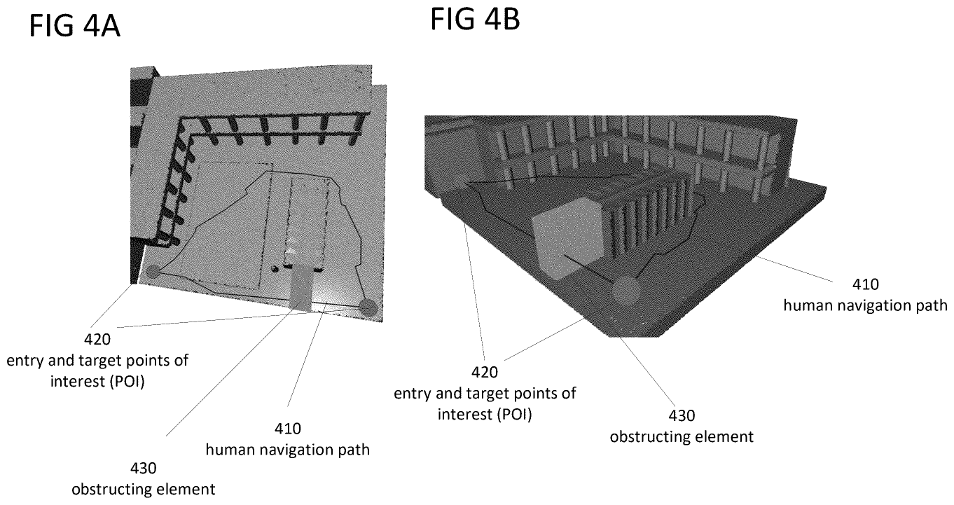

Referring to FIGS. 4A-4B, a cost-aware reachability planning example 400 may demonstrate how the system 100 performs motion planning under different obstruction conditions within an industrial environment. The cost-aware reachability planning example 400 may show a human navigation path 410 connecting an entry and target POI 420 under varying spatial constraints involving an obstructing element 430.

As shown in FIGS. In 4A-4B, the human navigation path 410 may be represented as lines connecting the entry and target POI 420, which may be marked as spheres within the environment. The entry and target POI 420 may represent locations where human operators need to access components or perform tasks within the industrial facility. The obstructing element 430 may be depicted as a geometric volume that imposes spatial constraints on human navigation.

In FIG. 4A, the human navigation path 410 may route around the obstructing element 430, resulting in a longer path that avoids collision with the obstruction. This routing behavior may demonstrate how the system 100 handles scenarios in which traversal costs exceed acceptable thresholds, prompting the motion planning algorithms to seek alternative routes that maintain accessibility while avoiding high-cost interactions with obstacles.

In FIG. 4B, the human navigation path 410 may pass through or near the obstructing element 430, representing a scenario in which the motion planning module 130 accepts a higher traversal cost to allow interaction with the dynamic obstruction. This approach may produce a shorter path that assumes the obstructing element 430 is removable or tolerable under specific operational conditions.

The system 100 may perform motion planning using a kinematic model by assigning traversal costs to one or more paths that intersect with one or more obstacles while maintaining connectivity through the one or more obstacles in the reachability graph 120. The motion planning process may distinguish between different types of obstructions based on their characteristics and impact on human navigation. In some cases, the one or more obstacles may comprise a static obstacle that fully blocks traversal or a dynamic obstacle that is assigned traversal costs based on spatial intrusion.

Static obstacles such as walls, permanent structural elements, or fixed equipment may be treated as hard constraints that fully block traversal within the reachability graph 120. When the motion planning module 130 encounters static obstacles, the motion planning algorithms may not create connections through these elements, instead routing around them to maintain path feasibility.

Dynamic obstacles, such as routed pipes, cable trays, or movable equipment, may be assigned traversal costs based on spatial intrusion rather than treated as absolute barriers. The system 100 may evaluate the degree of spatial intrusion caused by dynamic obstacles and assign corresponding cost values that reflect the difficulty or feasibility of traversing or approaching these elements.

The system 100 may assign traversal costs using a hierarchical approach that reflects different levels of path complexity and feasibility. In some cases, assigning traversal costs may comprise assigning zero cost to one or more paths through free space where no obstructions or constraints exist. The zero-cost assignment may indicate optimal routing conditions in which human operators can navigate freely without encountering spatial limitations or safety concerns.

The system 100 may assign a first cost to one or more paths that intersect with one or more obstacles, reflecting moderate spatial constraints or temporary obstructions. The first cost assignment may account for scenarios where human navigation is possible but requires additional effort, time, or coordination to navigate around or through dynamic elements within the environment.

The system 100 may assign a second cost, higher than the first, to one or more paths that require structural changes or significant modifications to the environment. The second cost assignment may indicate scenarios where accessibility can only be achieved through substantial alterations to the industrial layout, such as relocating equipment, rerouting pipes, or installing additional walkways or access structures.

The system 100 may evaluate reachability across a plurality of cost thresholds, each defining a maximum acceptable traversal cost for path planning and accessibility analysis. The cost threshold evaluation may enable the system 100 to generate graded accessibility assessments that reflect different levels of design flexibility and modification requirements.

For each cost threshold, the system 100 may construct a modified version of the reachability graph 120 by including only edges whose assigned costs are less than or equal to the specified threshold value. The graph search 140 may then perform standard search algorithms to identify reachable points of interest under the given cost constraints. This cost-sweep approach may yield a graded view of accessibility, ranging from fully clear paths at low thresholds to progressively more constrained paths at higher thresholds.

The system 100 may generate graded accessibility feedback indicating which of the one or more points of interest are accessible under each of the plurality of cost thresholds. The graded accessibility feedback may provide structured, data-driven information that enables designers to understand the relationship between design modifications and accessibility outcomes. In some cases, the graded feedback may indicate that specific points of interest become reachable only when certain cost thresholds are exceeded, thereby identifying the minimum level of design changes needed to restore accessibility.

The output generated by the system 100 may comprise a modification suggestion identifying an obstacle that prevents accessibility to an unreachable point of interest. The modification suggestions may provide actionable feedback that guides designers toward specific changes that can restore human operability within the industrial environment. In some cases, the modification suggestions may identify which dynamic obstacles should be relocated, resized, or removed to achieve accessibility at lower cost thresholds.

The system 100 may perform motion planning using sampling-based algorithms that handle complex spatial constraints and high-dimensional configuration spaces. In some cases, performing motion planning may involve using a sampling-based motion planning algorithm, such as a rapidly exploring random tree (RRT) or a probabilistic roadmap (PRM). These algorithms may enable the system 100 to explore feasible human-scale paths through constrained industrial environments where direct geometric connections are not available between navigable surfaces and points of interest.

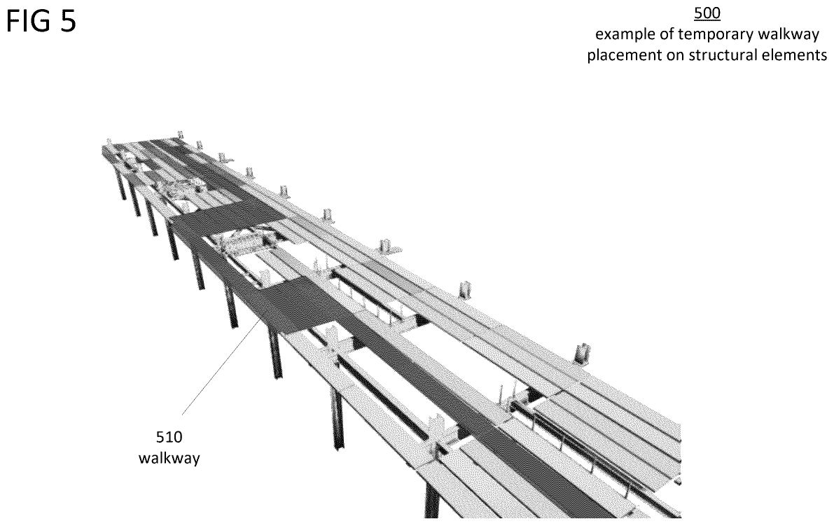

Referring to FIG. 5, a temporary walkway placement example 500 demonstrates how the system 100 expands reachable areas in elevated locations where permanent walkways are unavailable. The temporary walkway placement example 500 may include a walkway 510 positioned on supporting structural elements within an industrial environment. The walkway 510 may comprise multiple board or plank sections arranged to create a continuous path across structural framework elements.

As shown in FIG. 5, the walkway 510 may be positioned on horizontal beams and vertical support columns that provide a foundation for temporary walkway placement. The walkway 510 sections may be arranged to maintain connectivity between adjacent boards while avoiding collisions with environmental obstacles.

The system 100 may construct the reachability graph 120 by identifying one or more structural elements suitable for supporting one or more temporary structures. The identification process may involve semantic analysis of the semantically annotated 3D model 310 to locate structural beams, columns, and framework elements that possess adequate load-bearing capacity and spatial positioning for temporary walkway installation. In some cases, the semantic map 110 may provide structural classification information that enables the system 100 to distinguish between different types of structural elements based on their geometric properties and material characteristics.

The system 100 may simulate placement of the one or more temporary structures on the one or more structural elements to expand reachable areas within the industrial environment. The simulation process may use physics-based modeling to evaluate the stability and feasibility of temporary walkway placement on identified structural supports. In some cases, the simulation may involve placing removable walkway sections using planks and boards through physics simulation that accounts for gravitational forces, structural loading, and geometric constraints.

The system 100 may perform collision testing during the temporary structure placement simulation to remove unfeasible board locations that would interfere with existing equipment, routing elements, or other obstacles within the environment. The collision testing process may evaluate each proposed walkway section against the surrounding geometry to ensure that temporary structures do not create spatial conflicts or safety hazards. In some cases, the collision testing may identify locations where walkway sections cannot be placed due to insufficient clearance or interference with dynamic elements such as pipes or cable trays.

The system 100 may verify connectivity between adjacent boards during the temporary structure placement process to ensure that the resulting walkway 510 provides continuous navigation paths for human operators. The connectivity verification may evaluate spatial relationships between individual walkway sections to confirm that gaps, elevation changes, and alignment issues do not prevent safe traversal across the temporary structure. In some cases, the connectivity checking may identify locations where additional walkway sections or bridging elements are needed to maintain path continuity.

The temporary walkway placement example 500 may enable human operators to access elevated points of interest during construction or maintenance operations where fixed walkways are unavailable. The walkway 510 may provide temporary access solutions that expand the coverage of the reachability graph 120 without requiring permanent modifications to the industrial facility structure. In some cases, the temporary structures may be incorporated into the reachability graph 120 as additional navigable surfaces that connect previously isolated areas of the industrial environment.

The system 100 may integrate temporary structure placement capabilities into the motion planning module 130 to enhance path planning in complex industrial environments. The integration may enable the system 100 to consider both permanent and temporary navigation options when evaluating accessibility to points of interest throughout the facility. In some cases, the temporary structure placement may provide cost-effective alternatives to permanent walkway installation while maintaining human operability requirements during design and construction phases.

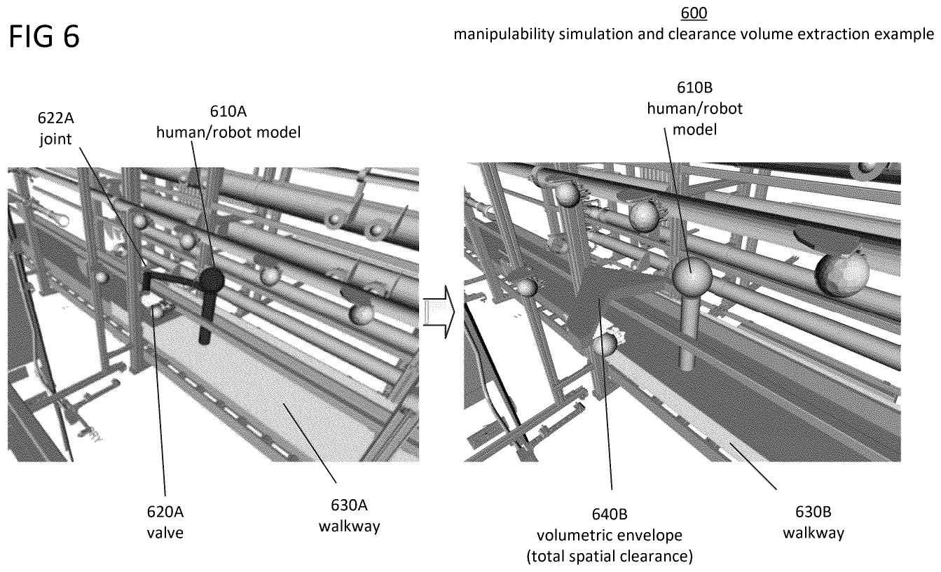

Referring to FIG. 6, a manipulability simulation and clearance volume extraction example 600 demonstrates how the system 100 evaluates whether an interaction is feasible at reachable points of interest using a kinematic model. The manipulability simulation and clearance volume extraction example 600 may be shown in two side-by-side perspective views of an industrial environment that illustrate different phases of the manipulability analysis process.

The left view of the manipulability simulation and clearance volume extraction example 600 may depict a human/robot model 610A positioned on a walkway 630A adjacent to a valve 620A. The human/robot model 610A may include a joint 622A, which represents an articulated limb structure used to simulate manipulation motions in the industrial environment. The valve 620A may be mounted on industrial piping infrastructure, and the human/robot model 610A may be shown in a configuration for performing a manipulation task on the valve 620A.

The kinematic model may represent an anthropomorphic agent that is a human operator or a humanoid robot with articulated limb structures and defined joint constraints. In some cases, the kinematic model may be defined in Unified Robot Description Format (URDF) with joint limits based on human ergonomic constraints. The URDF format may provide a widely adopted Extensible Markup Language (XML)-based representation for describing rigid-body systems, including links, joints, and joint limits, within robotics applications.

The human/robot model 610A may represent a 50th percentile adult male with articulated limbs and defined joint ranges for shoulder, elbow, and wrist components. The joint ranges may be derived from ergonomic studies that establish realistic constraints for human motion capabilities within industrial environments. In some cases, each joint may have physical limits derived from ergonomic research, and a torso component may be fixed to a base node on the walkway 630A to provide a stable reference frame for motion simulation.

The system 100 may evaluate whether an interaction is performable by using the motion planning module 160 to generate collision-free joint-space trajectories from a current arm configuration to follow a desired end-effector path. The motion planning module 160 may use sampling-based algorithms to generate collision-free joint-space trajectories that account for spatial constraints and obstacle-avoidance requirements.

The motion planning module 160 may operate in joint space using angular coordinates or task space using Cartesian end-effector tracking, depending on the nature of the trajectory being executed. Joint-space motion planning may involve direct manipulation of joint angles to achieve desired end-effector positions, while task-space planning may focus on Cartesian-coordinate tracking of the end-effector in three-dimensional space. The selection between joint-space and task-space approaches may depend on the specific manipulation requirements and spatial constraints encountered at each point of interest.

The system 100 may detect any collisions during execution of the transformed trajectory by using the URDF model's kinematics and collision geometry to validate all intermediate steps against surrounding geometry, including pipes, supports, and cable trays. The collision detection process may evaluate each intermediate configuration along the planned trajectory to ensure that no part of the human/robot model 610A intersects with obstacles or structural elements within the environment.

As further shown in FIG. 6, the right view may show a human/robot model 610B positioned on a walkway 630B, with a volumetric envelope 640B displayed around the human/robot model 610B. The volumetric envelope 640B may represent the total spatial clearance required to perform the manipulation task, aggregating all three-dimensional positions occupied by the human/robot model 610B during execution of the manipulation trajectory.

The system 100 may extract a clearance volume representing the space required for the interaction and provide it as an exclusion zone for routing tools. The clearance volume extraction process may record all 3D positions occupied by the human's arm and body during motion execution and aggregate these positions into the volumetric envelope 640B for reuse as static exclusion zones in subsequent design iterations.

The volumetric envelope 640B may be depicted as a semi-transparent volume that encompasses the space traversed by the articulated limbs during the simulated motion. Once a trajectory for manipulability is successfully executed for a given valve type, all 3D positions occupied by the human/robot model 610B during the motion may be recorded and stored for future reference. The volumetric envelope 640B may be stored and reused to define a static exclusion zone around each valve in future design passes, enabling automated routing tools to treat these volumes as obstacles during path planning.

The system 100 may provide the clearance volume as an exclusion zone for routing tools, preventing routed elements, such as pipes or cable trays, from intruding into the space required for human motion. This approach may allow routing tools to ensure manipulability without repeating full motion planning simulations, offering a tradeoff between computational efficiency and geometric precision during iterative design processes.

The endpoint analysis module 150 may evaluate whether required interactions are performable by determining the feasibility of a manipulation action, line-of-sight observation, or bidirectional construction access at each reachable point of interest. The manipulation action evaluation may verify that sufficient spatial clearance exists for the human/robot model 610A to complete the required task without colliding with or interfering with surrounding obstacles. In some cases, the feasibility determination may generate a binary feasibility flag indicating whether manipulation is possible, along with diagnostic information describing failure causes such as elbow collision with pipes or insufficient clearance above shoulder joints.

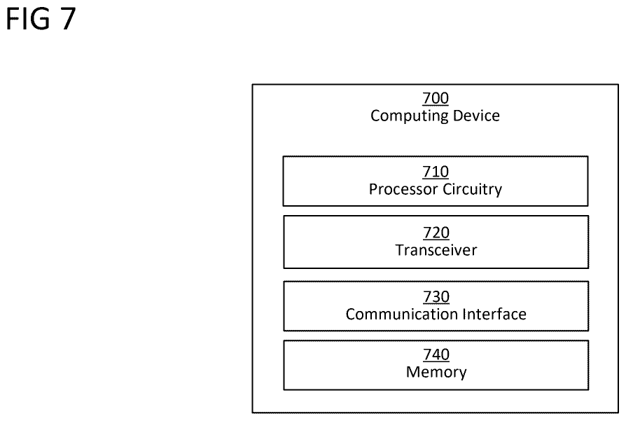

Referring to FIG. 7, a computing device 700 may implement the system 100 functionality through hardware components configured to perform human-aware reachability and manipulability analysis for industrial design automation. The computing device 700 may include processor circuitry 710, a transceiver 720, a communication interface 730, and memory 740 arranged to support computational operations and data processing requirements.

The processor circuitry 710 may execute instructions and perform computational operations for the computing device 700. In some cases, the processor circuitry 710 may comprise one or more processors configured to execute instructions stored in the memory 740 to cause the computing device 700 to perform reachability analysis and manipulability verification operations. The processor circuitry 710 may process three-dimensional data representing industrial environments and execute algorithms for motion planning, graph construction, and accessibility evaluation.

The processor circuitry 710 may execute instructions that cause the computing device 700 to receive three-dimensional data comprising navigable surfaces, points of interest, and obstacles within industrial environments. The processor circuitry 710 may implement the semantic map 110 functionality by processing CAD data to extract spatial information, object identities, and semantic annotations. In some cases, the processor circuitry 710 may construct the reachability graph 120 by generating nodes and edges representing human-navigable connections between entry points and points of interest.

The processor circuitry 710 may perform motion planning using kinematic models by executing sampling-based algorithms, such as RRT or PRM. The processor circuitry 710 may assign traversal costs to paths that intersect with obstacles while maintaining connectivity through dynamic elements in the reachability graph 120. In some cases, the processor circuitry 710 may evaluate reachability under multiple cost thresholds and generate graded accessibility feedback indicating which points of interest are accessible under different constraint conditions.

The transceiver 720 may enable wireline or wireless communication capabilities, allowing the computing device 700 to send and receive data related to industrial design automation processes. The transceiver 720 may facilitate data exchange with external CAD systems, design tools, or remote computing resources that provide three-dimensional environmental data or receive accessibility analysis results.

The communication interface 730 may facilitate data exchange between the computing device 700 and external systems or networks involved in industrial design workflows. In some cases, the communication interface 730 may enable the computing device 700 to receive CAD data from design systems and transmit accessibility feedback to automated routing tools or design validation systems. The communication interface 730 may support various communication protocols and data formats used in industrial design automation environments.

The memory 740 may store data, instructions, and other information used by the processor circuitry 710 during operation. The memory 740 may store instructions that, when executed by the processor circuitry 710, cause the computing device 700 to perform human-aware reachability and manipulability analysis operations. In some cases, the memory 740 may store the manipulation database 170, which contains reference trajectories for various component types, semantic map 110 data structures, and reachability graph 120 representations.

The memory 740 may store instructions that cause the processor circuitry 710 to construct reachability graphs representing connections between navigable surfaces and points of interest using kinematic models. The stored instructions may enable the processor circuitry 710 to perform motion planning by assigning traversal costs to paths that intersect with obstacles while maintaining connectivity through the obstacles. In some cases, the memory 740 may store instructions that cause the processor circuitry 710 to evaluate reachability to points of interest based on traversal costs and generate accessibility feedback identifying reachability and interaction feasibility.

The computing device 700 may be configured to perform various functions related to industrial design automation, including reachability analysis, manipulability verification, and human-aware validation of industrial facility layouts. The processor circuitry 710 may execute instructions stored in the memory 740 to implement the endpoint analysis module 150 functionality, including evaluating manipulation actions, performing line-of-sight observation, and providing bidirectional construction access at reachable points of interest.

The computing device 700 may be embodied as a non-transitory computer-readable storage medium storing instructions that cause a computing system to perform the described operations. The non-transitory computer-readable storage medium may store instructions that, when executed by one or more processors, cause the computing system to receive three-dimensional data representing an environment and construct reachability graphs using kinematic models. In some cases, the non-transitory computer-readable storage medium may store instructions that cause the computing system to perform motion planning by assigning traversal costs to paths intersecting with obstacles and evaluate reachability under multiple cost thresholds to generate graded accessibility feedback.

The system 100 may perform line-of-sight analysis to determine whether the one or more points of interest are visually accessible from the one or more navigable surfaces. The line-of-sight analysis may be performed for gauges and other visual components that require direct visual observation by human operators during industrial operations. In some cases, the line-of-sight analysis may sample several human eye positions at standing height from the nearest floor or catwalk node within the reachability graph 120.

The system 100 may cast rays from each sampled eye position toward a gauge face center to evaluate visual accessibility. The ray casting process may check for obstacles in the environment, including tools, pipes, cable trays, and other structural elements that may obstruct the line of sight between the human operator and the gauge. In some cases, a gauge may be considered visible if at least one ray arrives unobstructed at the gauge face center from a valid standing position.

The line-of-sight analysis may account for both line-of-sight constraints and field-of-view constraints when evaluating gauge visibility. The analysis may detect visibility violations for gauges mounted at awkward angles or surrounded by obstructions, which may go unnoticed until commissioning phases of industrial facility deployment. In some cases, the line-of-sight analysis may provide early detection of visual accessibility issues that can be addressed during the design phase rather than during field installation.

The system 100 may verify bidirectional access by determining whether a path exists for both approach to and retreat from the points of interest. The bidirectional access verification may be performed for points of interest that involve construction activities, component installation, or maintenance operations where human operators must safely enter and exit confined areas. In some cases, the bidirectional access verification may compute a return path from a POI node back to a nearest entry point within the reachability graph 120.

The system 100 may simulate motion with a human footprint volume while optionally holding a component-sized bounding box during the bidirectional access verification process. The component-sized bounding box may represent equipment such as pumps, panels, or other components that human operators may carry during construction or maintenance activities. In some cases, the system 100 may check edges traversed during placement in reverse to detect asymmetric constraints, such as crouching to enter but being unable to turn around and exit safely.

The bidirectional access verification may flag points of interest as non-constructable under a current configuration if a return path cannot be verified. The verification process may identify scenarios where human operators can reach a location but cannot retreat safely due to spatial constraints, equipment interference, or geometric limitations within the industrial environment.

The system 100 may simulate movement through the environment while carrying a payload by modifying spatial constraints during motion planning to account for payload dimensions. The payload simulation may support scenarios where human operators must move through the industrial environment while carrying tools, equipment, or large components that impose additional spatial constraints beyond those of unencumbered motion. In some cases, the standard human model may be replaced with a bulkier model that includes payload dimensions, such as panels, crates, or tool bags.

The motion planning module 130 may be reconfigured to enforce additional kinematic and geometric constraints during payload simulation. The additional constraints may include minimum turning radius requirements, modified stride length parameters, two-arm balance considerations, or two-person coordination requirements, depending on the payload characteristics and handling requirements. In some cases, the motion planning algorithms may verify whether component placement zones allow for safe approach, manipulation, and retreat without collisions or spatial bottlenecks when carrying payloads.

The system 100 may be implemented using modern motion planning libraries that support arbitrary bounding geometries, compound kinematic chains, and constraint-aware planning. These motion planning libraries may provide flexibility for incorporating payload simulation capabilities into the existing framework without requiring architectural changes to the system 100. In some cases, the motion planning libraries may leverage established robotics capabilities to simulate realistic human-equipment interaction in industrial environments.

The system 100 may iteratively re-evaluate reachability in response to user-specified modifications to the environment. The iterative re-evaluation capability may enable designers to make changes to industrial facility layouts and immediately assess their impact on human accessibility and operability. In some cases, the system 100 may update the semantic map 110 and reachability graph 120 in response to modifications such as equipment relocation, route changes, or structural alterations.

The iterative re-evaluation process may provide real-time feedback during design iterations, allowing designers to explore different configuration options while maintaining awareness of human operability constraints. The system 100 may recalculate traversal costs, update motion planning results, and regenerate accessibility feedback each time user-specified modifications are applied to the environment representation.

The system 100 may generate accessibility feedback identifying reachability and interaction feasibility for the one or more points of interest. The accessibility feedback may include graded accessibility feedback indicating which of the one or more points of interest are accessible under each of a plurality of cost thresholds. In some cases, the graded feedback may provide structured information about the relationship between design modifications and accessibility outcomes across different constraint levels.

The system 100 may generate diagnostic reports describing the causes of failures when points of interest are determined to be unreachable or non-manipulable. The diagnostic reports may include specific information such as elbow collision with a pipe, insufficient clearance above the shoulder, or other spatial constraint violations that prevent successful task completion. In some cases, the diagnostic reports may identify the specific obstacles or geometric constraints that cause accessibility failures.

The system 100 may provide visual playback of attempted motions, highlighting collisions or unreachable targets for analysis purposes. The visual playback capability may enable designers to observe the motion planning process and understand why specific manipulation tasks fail or succeed within the spatial constraints of the industrial environment. In some cases, the visual playback may display collision points, joint limit violations, or trajectory deviations that contribute to task failure, providing detailed feedback for design optimization.

The techniques described in this disclosure may also be illustrated in the following examples.

Example 1. A system, comprising: one or more processors; and a memory storing instructions that, when executed by the one or more processors, cause the system to: receive three-dimensional (3D) data representing an environment, the 3D data comprising one or more navigable surfaces, one or more points of interest, and one or more obstacles; construct a reachability graph representing connections between the one or more navigable surfaces and the one or more points of interest; perform motion planning using a kinematic model by assigning traversal costs to one or more paths that intersect with one or more obstacles while maintaining connectivity through the one or more obstacles in the reachability graph; evaluate reachability to the one or more points of interest based on the traversal costs; and generate output identifying which of the one or more points of interest are reachable.

Example 2. The system of example 1, wherein the one or more obstacles comprise a static obstacle that fully blocks traversal or a dynamic obstacle that is assigned traversal costs based on spatial intrusion.

Example 3. The system of any one or more of examples 1-2, wherein assigning traversal costs comprises: assigning zero cost to one or more paths through free space; assigning a first cost to one or more paths that intersect with one or more obstacles; and assigning a second cost higher than the first cost to one or more paths requiring structural changes.

Example 4. The system of any one or more of examples 1-3, wherein the instructions further cause the system to evaluate reachability under a plurality of cost thresholds, wherein each of the plurality of cost thresholds defines a maximum acceptable traversal cost.

Example 5. The system of any one or more of examples 1-4, wherein the output comprises a modification suggestion identifying an obstacle that prevents accessibility to an unreachable point of interest.

Example 6. The system of any one or more of examples 1-5, wherein the instructions further cause the system to evaluate whether an interaction is performable at reachable points of interest using the kinematic model.

Example 7. The system of any one or more of examples 1-6, wherein the kinematic model represents an anthropomorphic agent that is a human operator or a humanoid robot.

Example 8. The system of any one or more of examples 1-7, wherein evaluating whether an interaction is performable comprises: accessing a database of one or more reference trajectories associated with one or more interaction types; transforming a reference trajectory to a pose of a component at a point of interest; and detecting any collisions during execution of the transformed trajectory.

Example 9. The system of any one or more of examples 1-8, wherein the instructions further cause the system to extract a clearance volume representing space required for the interaction and provide the clearance volume as an exclusion zone for routing tools.

Example 10. The system of any one or more of examples 1-9, wherein performing motion planning comprises using a sampling-based motion planning algorithm selected from a rapidly exploring random tree (RRT) and a probabilistic roadmap (PRM).

Example 11. The system of any one or more of examples 1-10, wherein the 3D data comprises one or more semantic annotations identifying one or more object types selected from walkable surfaces, stairs, ladders, valves, gauges, and entry points.

Example 12. The system of any one or more of examples 1-11, wherein constructing the reachability graph comprises: identifying one or more structural elements suitable for supporting one or more temporary structures; and simulating placement of the one or more temporary structures on the one or more structural elements to expand reachable areas.

Example 13. The system of any one or more of examples 1-12, wherein the instructions further cause the system to verify bidirectional access by determining whether a path exists for both approach to and retreat from the points of interest.

Example 14. The system of any one or more of examples 1-13, wherein the instructions further cause the system to perform line-of-sight analysis to determine whether the one or more points of interest are visually accessible from the one or more navigable surfaces.

Example 15. The system of any one or more of examples 1-14, wherein the instructions further cause the system to simulate movement through the environment while carrying a payload by modifying spatial constraints during motion planning to account for payload dimensions.

Example 16. The system of any one or more of examples 1-15, wherein the instructions further cause the system to iteratively re-evaluate reachability in response to user-specified modifications to the environment.

Example 17. A non-transitory computer-readable storage medium storing instructions that, when executed by one or more processors, cause a computing system to: receive three-dimensional (3D) data representing an environment, the 3D data comprising one or more navigable surfaces, one or more points of interest, and one or more obstacles; construct a reachability graph representing connections between the one or more navigable surfaces and the one or more points of interest using a kinematic model; perform motion planning by assigning traversal costs to one or more paths that intersect with the one or more obstacles while maintaining connectivity through the one or more obstacles in the reachability graph; evaluate reachability to the one or more points of interest based on the traversal costs; for reachable points of interest, evaluate whether required interactions are performable using the kinematic model; and generate accessibility feedback identifying reachability and interaction feasibility for the one or more points of interest.

Example 18. The computer-readable storage medium of example 17, wherein the instructions further cause the computing system to evaluate reachability under a plurality of cost thresholds and generate graded accessibility feedback indicating which of the one or more points of interest are accessible under each of the plurality of cost thresholds.

Example 19. The computer-readable storage medium of any one or more of examples 17-18, wherein the kinematic model is defined in Unified Robot Description Format (URDF) with joint limits based on human ergonomic constraints.

Example 20. The computer-readable storage medium of any one or more of examples 17-19, wherein evaluating whether required interactions are performable comprises determining feasibility of a manipulation action, line-of-sight observation, or bidirectional construction access.

A number of implementations have been described. Nevertheless, it will be understood that various modifications may be made without departing from the spirit and scope of the disclosure. Accordingly, other implementations are within the scope of the following claims.

1. A system, comprising:
one or more processors; and
a memory storing instructions that, when executed by the one or more processors, cause the system to:
receive three-dimensional (3D) data representing an environment, the 3D data comprising one or more navigable surfaces, one or more points of interest, and one or more obstacles;
construct a reachability graph representing connections between the one or more navigable surfaces and the one or more points of interest;
perform motion planning using a kinematic model by assigning traversal costs to one or more paths that intersect with one or more obstacles while maintaining connectivity through the one or more obstacles in the reachability graph;
evaluate reachability to the one or more points of interest based on the traversal costs; and
generate output identifying which of the one or more points of interest are reachable.

2. The system of claim 1, wherein the one or more obstacles comprise a static obstacle that fully blocks traversal or a dynamic obstacle that is assigned traversal costs based on spatial intrusion.

3. The system of claim 1, wherein assigning traversal costs comprises:
assigning zero cost to one or more paths through free space;
assigning a first cost to one or more paths that intersect with one or more obstacles; and
assigning a second cost higher than the first cost to one or more paths requiring structural changes.

4. The system of claim 1, wherein the instructions further cause the system to evaluate reachability under a plurality of cost thresholds, wherein each of the plurality of cost thresholds defines a maximum acceptable traversal cost.

5. The system of claim 1, wherein the output comprises a modification suggestion identifying an obstacle that prevents accessibility to an unreachable point of interest.

6. The system of claim 1, wherein the instructions further cause the system to evaluate whether an interaction is performable at reachable points of interest using the kinematic model.

7. The system of claim 6, wherein the kinematic model represents an anthropomorphic agent that is a human operator or a humanoid robot.

8. The system of claim 6, wherein evaluating whether an interaction is performable comprises:
accessing a database of one or more reference trajectories associated with one or more interaction types;
transforming a reference trajectory to a pose of a component at a point of interest; and
detecting any collisions during execution of the transformed trajectory.

9. The system of claim 8, wherein the instructions further cause the system to extract a clearance volume representing space required for the interaction and provide the clearance volume as an exclusion zone for routing tools.

10. The system of claim 1, wherein performing motion planning comprises using a sampling-based motion planning algorithm selected from a rapidly exploring random tree (RRT) and a probabilistic roadmap (PRM).

11. The system of claim 1, wherein the 3D data comprises one or more semantic annotations identifying one or more object types selected from walkable surfaces, stairs, ladders, valves, gauges, and entry points.

12. The system of claim 1, wherein constructing the reachability graph comprises:
identifying one or more structural elements suitable for supporting one or more temporary structures; and
simulating placement of the one or more temporary structures on the one or more structural elements to expand reachable areas.

13. The system of claim 1, wherein the instructions further cause the system to verify bidirectional access by determining whether a path exists for both approach to and retreat from the points of interest.

14. The system of claim 1, wherein the instructions further cause the system to perform line-of-sight analysis to determine whether the one or more points of interest are visually accessible from the one or more navigable surfaces.

15. The system of claim 1, wherein the instructions further cause the system to simulate movement through the environment while carrying a payload by modifying spatial constraints during motion planning to account for payload dimensions.

16. The system of claim 1, wherein the instructions further cause the system to iteratively re-evaluate reachability in response to user-specified modifications to the environment.

17. A non-transitory computer-readable storage medium storing instructions that, when executed by one or more processors, cause a computing system to:
receive three-dimensional (3D) data representing an environment, the 3D data comprising one or more navigable surfaces, one or more points of interest, and one or more obstacles;
construct a reachability graph representing connections between the one or more navigable surfaces and the one or more points of interest using a kinematic model;
perform motion planning by assigning traversal costs to one or more paths that intersect with the one or more obstacles while maintaining connectivity through the one or more obstacles in the reachability graph;
evaluate reachability to the one or more points of interest based on the traversal costs;
for reachable points of interest, evaluate whether required interactions are performable using the kinematic model; and
generate accessibility feedback identifying reachability and interaction feasibility for the one or more points of interest.

18. The computer-readable storage medium of claim 17, wherein the instructions further cause the computing system to evaluate reachability under a plurality of cost thresholds and generate graded accessibility feedback indicating which of the one or more points of interest are accessible under each of the plurality of cost thresholds.

19. The computer-readable storage medium of claim 17, wherein the kinematic model is defined in Unified Robot Description Format (URDF) with joint limits based on human ergonomic constraints.

20. The computer-readable storage medium of claim 17, wherein evaluating whether required interactions are performable comprises determining feasibility of a manipulation action, line-of-sight observation, or bidirectional construction access.
